(19) United States
(12) Patent Application Publication
(10) Pub. No.: US 2014/0332197 A1
(43) Pub. Date: Nov. 13, 2014

(54) Air Conditioner Terminal Device, Air Conditioning Apparatus And Data Center

(71) Applicant: Carrier Corporation, Farmington, CT (US)

(72) Inventors: YuHui Kuang, Shanghai (CN); Robert Hong-Leung Chiang, Shanghai (CN); Michel Grabon, Bressolles (FR); Lijia Jessica Zhao, Shanghai (CN)

(21) Appl. No.: 14/358,105

(22) PCT Filed: Nov. 15, 2012
(86) PCT No.: PCT/US2012/065153

§ 371 Date: May 14, 2014

(30) Foreign Application Priority Data
Nov. 15, 2011 (CN) 201120451151.0

(51) Int. Cl. H05K 7/20

(52) U.S. Cl. CPC H05K 7/20718; H05K 7/20836
USPC 165/287; 165/104.14

(57) ABSTRACT

An air conditioner terminal device (100) and a data center comprising the air conditioner terminal device, wherein the air conditioner terminal device (100) comprises a heat exchanger (12), a variable-speed fan (22), an air passage (101) communicating from an air suction port (11) to an air discharge port (21), and refrigerant flowing through the heat exchanger. The heat exchanger (12) and fan (22) are installed in the air passage (101), and the fan (22) forces air within the air passage (101) to flow towards the air discharge port (21) from the air suction port (11). The refrigerant comes into heat contact with air within the air passage (101) via the heat exchanger (12). The heat exchanger has an input joint (121) and an output joint (122), the refrigerant flows in via the input joint (121) and flows out the output joint (122). The refrigerant inside the input joint (121) is liquid-phase fluid, whereas the refrigerant inside the output joint (122) is gas-liquid two-phase fluid or gas-phase fluid.

### FIELD OF THE INVENTION

The invention relates to the technical field of air conditioner, and in particular to an air conditioner terminal device, an air conditioning apparatus having the air conditioner terminal device and a data center having the air conditioning apparatus.

### BACKGROUND

A data center comprises numerous data devices having high heat density electronic loads, such as computer, server, etc. Sensible heat generated by such loads is higher than that of a general cozy environment. Moreover, a non-stopped refrigerating for 365 days a year, 24 hours a day is required. Heat generation and sensitivities of electronic components require that the temperature, humidity, air flow and air cleanliness in the machine room must be maintained within a strict range, and that a highly stable operating environment is maintained. With continuous development of modern technologies, the scale of data center is being increasingly enlarged, and heat density of load is becoming higher and higher, thus causing more problems to heat processing of the machine room. Besides, higher requirements have been raised on reliability, high efficiency and energy-saving operation of air conditioning system.

Conventional hydronic fan coil unit (FCU) uses water as fluid medium in conduit, and changes capacity thereof via rotational speed of fan and opening degree of water valve. However, due to safety issue, the conventional hydronic fan coil unit is not suitable for a no-water-entry data center.

In addition, for a variable refrigerant flow (VRF) air conditioning system, it is required to achieve a refrigerant flow control via rotational speed of fan and refrigerant expansion valve so that the refrigerant is distributed into units inside the VRF air conditioning system so as to complete a refrigerating cycle. However, such the refrigerant flow control is extremely complex.

It is therefore necessary to provide improved technical solutions to overcome technical problems existing in the prior art.

### SUMMARY

The main technical problem to be solved by the invention is to realize providing cooling for variable heat generating loads without complex refrigerant flow control.

The invention provides the following technical solutions in order to solve the above technical problem.

One aspect of the invention provides an air conditioner terminal device comprising a heat exchanger, a variable-speed fan, an air passage communicating from an air suction port to an air discharge port, and refrigerant flowing through the heat exchanger, wherein the heat exchanger and the fan are installed in the air passage, the fan forces air within the air passage to flow towards the air discharge port from the air suction port, the refrigerant comes into heat contact with air within the air passage via the heat exchanger, the heat exchanger has an input joint and an output joint, the refrigerant flows in via the input joint and flows out from the output joint, and the refrigerant inside the input joint is liquid-phase fluid, whereas the refrigerant inside the output joint is gas-liquid two-phase fluid or gas-phase fluid.

Optionally, in the above air conditioner terminal device, the air conditioner terminal device further comprises a temperature sensor for monitoring temperature in the air passage and a controller. The controller is associated with the temperature sensor and the fan, and is arranged to vary the rotational speed of the fan according to the temperature detected by the temperature sensor.

Optionally, in the above air conditioner terminal device, the temperature sensor comprises a first temperature sensor and a second temperature sensor, wherein the first temperature sensor is positioned between the air suction port and the heat exchanger, and the second temperature sensor is positioned between the heat exchanger and the air discharge port.

Optionally, in the above air conditioner terminal device, the fan is a variable-frequency axial flow fan, and the controller is arranged to automatically adjust the rotational speed of the fan according to the difference between temperatures detected by the first temperature sensor and the second temperature sensor respectively.

Another aspect of the invention provides an air conditioning apparatus comprising the above-described air conditioner terminal device, a condenser, a pump and a circulating pipeline communicating the air conditioner terminal device, the condenser and the pump, wherein the pump forces refrigerant to circulate between the air conditioner terminal device and the condenser via the circulating pipeline.

Yet another aspect of the invention provides a data center comprising a plurality of data device racks and the above-described air conditioning apparatus, wherein each rack has opposite first and second sides, one said air conditioner terminal device is provided above each rack, the air suction port is located above the first side and the air discharge port is located above the second side.

According to the invention, since the heat exchanger and the variable-speed fan is provided in the air passage and the heat exchanger is arranged so that the refrigerant can flow into the heat exchanger in a liquid-phase fluid an can flow out of the heat exchanger in a gas-liquid two-phase fluid or a gas-phase fluid after conducting heat exchange with air within the air passage, resulting in massive heat absorption during phase transition of refrigerant, therefore an on-site cooling can be provided to the high heat density loads via a simple refrigerant circulation, its structure is simple and no complex refrigerant flow control is needed. In addition, the air conditioner terminal device according to the invention can work efficiently and have high reliability due to its simple structure and control.

In another aspect, the air conditioner terminal device can vary the rotational speed of the fan automatically based on different air temperatures detected by the temperature sensor. Moreover, the refrigerating capacity of the air conditioner terminal device can be adjusted merely by simply varying the rotational speed of the fan so that an auto-adaptive capacity control of the air conditioner terminal device can be realized without complex refrigerant flow control.

In yet another aspect, the air conditioner terminal device can know about the change of load requirements according to temperature difference between inflow air temperature and outflow air temperature detected by the first temperature sensor and the second temperature sensor respectively so as to adjust rotational speed of the fan automatically, thus varying air volume of the fan and adjusting refrigerating capacity accurately and automatically.

Other aspects and features of the invention will become apparent from the detailed description made below with reference to the accompanying drawings. However, it should be understood that the accompanying drawings are designed only for explanation purpose, rather than limiting the scope of the invention which should be referred to the appended claims. It should be also noted that unless otherwise indicated, the drawings are not necessarily drawn to scale, since they merely attempt to schematically depict the structure and workflow described herein.

### BRIEF DESCRIPTION OF THE DRAWINGS

The invention will be more fully understood with reference to the following detailed description of the embodiments when read in conjunction with the accompanying drawings in which like reference numbers denote like elements, wherein:

FIG. 1 is a schematic structural view of an air conditioner terminal device in accordance with an embodiment; and

FIG. 2 is a schematic structural view of a data center in accordance with an embodiment.

### DETAILED DESCRIPTION OF THE INVENTION

The embodiments of the invention will be described in detail below with reference to the accompanying drawings in order that the above objectives, features and advantages of the invention will become more apparent and more easily understood.

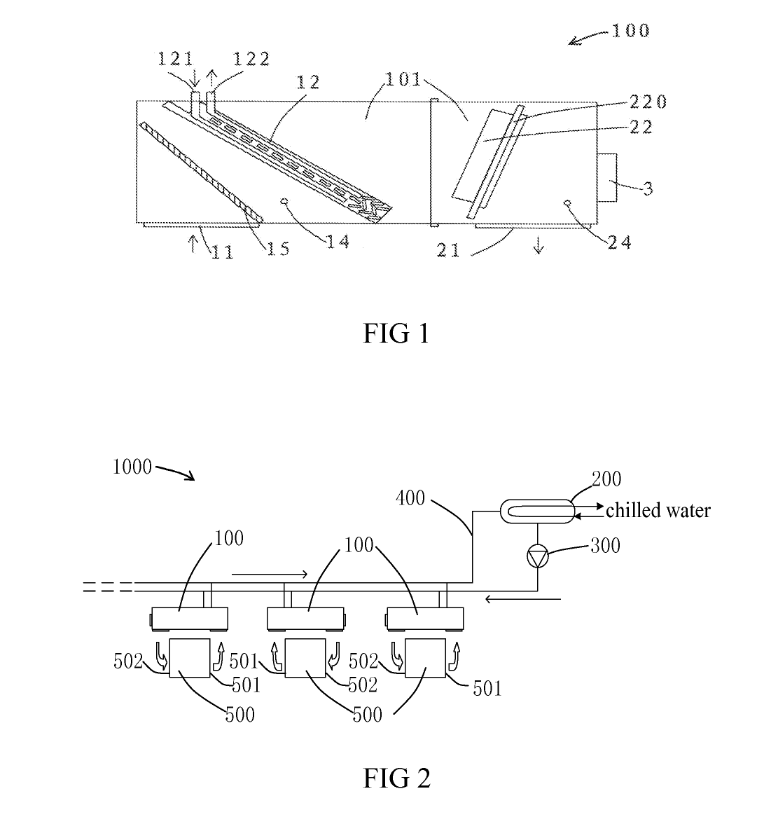

FIG. 1 illustrates a schematic structural view of an air conditioner terminal device in accordance with an embodiment. As shown in FIG. 1, an air conditioner terminal device 100 in accordance with an embodiment comprises an air passage 101 communicating from an air suction port 11 to an air discharge port 21. A heat exchanger 12 and a variable-speed fan 22 are installed in the air passage 101. The fan 22 forces air within the air passage 101 to flow towards the air discharge port 21 from the air suction port 11. The refrigerant circulates via the heat exchanger 12 which is arranged to make the refrigerant come into heat contact with air within the air passage 101 so that the refrigerant conducts heat exchange with air flowing through the air passage 101. The heat exchanger 12 has an input joint 121 and an output joint 122. The refrigerant flows in via the input joint 121 and flows out from the output joint 122, and the refrigerant inside the input joint 121 is liquid-phase fluid, whereas the refrigerant inside the output joint 122 is gas-liquid two-phase fluid or gas-phase fluid. The air conditioner terminal device 100 in accordance with the invention is provided with the variable-speed fan 22 and the heat exchanger 12 in the air passage 101, and the exchanger 12 is arranged so that the refrigerant can flow into the exchanger 12 in a liquid-phase fluid and flow out of the heat exchanger 12 in a gas-liquid two-phase fluid and a gas-phase fluid after conducting heat exchange with air inside the air passage 101, resulting in massive heat absorption during phase transition of refrigerant. Therefore, an on-site cooling can be provided to electronic loads having high heat density via a simple refrigerant circulation and the high energy density in the data center can be effectively managed. Moreover, its structure is simple and no complex refrigerant flow control is needed. In addition, due to simple structure and control of the air conditioner terminal device 100, it can work efficiently and have high reliability.

In an embodiment, the air conditioner terminal device 100 comprises a fan plate 220 extending between the whole circulation sections of the air passage 101. The fan plate 220 is provided with fan holes (not shown in the figures) therein and the fan 22 is installed in the fan holes. In an embodiment, the heat exchanger 12 is a coil heat exchanger 12 having an input joint 121 and an output joint 122. The refrigerant of the heat exchanger 12 flows in via the input joint 121 and flows out from the output joint 122 after circulating through the heat exchanger 12. Optionally, the heat exchanger 12 is a copper tube structure with aluminum fins, wherein phase transitioned refrigerant is inside the tube and air flow is outside the tube. The refrigerant is liquid-phase when entering the input joint 121 of the heat exchanger 12 and is gas-liquid two-phase when reaching the output joint 122 of the heat exchanger 12 after conducting heat exchange with air via copper tubes when circulating inside tubes. In an alternative embodiment, the refrigerant is liquid-phase when entering the input joint 121 of the heat exchanger 12 and is gas-phase fluid when reaching the output joint 122 of the heat exchanger 12. The refrigerant in gas phase may have a certain degree of overheat, but the functions of the air conditioner can still be realized.

The heat exchanger 12 employs oil-free refrigerant inside, and the oil-free refrigerant circulates in the heat exchanger 12 and conducts heat exchange with air flowing through the air passage 101. Since oil-free refrigerant is used inside the heat exchanger 12, a clean environment can be reliably maintained inside the data center. For example, in an embodiment, carbon dioxide is used as the refrigerant, of which the pressure ranges from 39 bar to 72 bar and the operating temperature ranges from 5 to 30° C. In an optional embodiment, the flow rate of refrigerant in the air conditioner terminal device 100 is 0.1 to 1 m3/hour.

The air conditioner terminal device 100 comprises a temperature sensor 14, 24 for monitoring air temperature in the air passage 101 and a controller 3, wherein all of the control functions of the controller 3 can be realized by use of a single chip microcomputer. The controller 3 is associated with the temperature sensor 14, 24 and the fan 22, and the controller 3 is arranged so that the rotational speed of the fan 22 varies according to the temperature detected by the temperature sensor 14, 24. The air conditioner terminal device 100 can vary the rotational speed of the fan 22 automatically based on different air temperatures detected by the temperature sensor 14, 24. Moreover, the refrigerating capacity of the air conditioner terminal device 100 can be adjusted merely by simply varying the rotational speed of the fan 22 so that an auto-adaptive capacity control of the air conditioner terminal device 100 can be realized without complex refrigerant flow control.

The temperature sensor 14, 24 comprises a first temperature sensor 14 and a second temperature sensor 24. In an embodiment, the first temperature sensor 14 is located between the air suction port 11 and the heat exchanger 12 for detecting inflow air temperature in the air passage 101. In an optional embodiment, an air filter 15 is further provided between the air suction port 11 and the heat exchanger 12, and the first temperature sensor 14 is located between the air filter 15 and the heat exchanger 12, that is, the air filter 15 is located above the air suction port 11, the heat exchanger 12 is located downstream of the air filter 15, and the first temperature sensor 14 is provided between the air filter 15 and the heat exchanger 12. The second temperature sensor 24 is located between the air discharge port 21 and the heat exchanger 12 for detecting the outflow air temperature in the air passage 101. In an embodiment, the second temperature sensor 24 is provided between the air discharge port 21 and the fan 22, i.e., the second temperature sensor 24 is disposed downstream of the fan 22 and upstream of the air discharge port 21.

In an embodiment, the fan 22 is a variable-frequency axial flow fan 22, and the controller 3 is arranged to automatically adjust the rotational speed of the fan 22 according to the difference between temperatures detected by the first temperature sensor 14 and the second temperature sensor 24 respectively. Two input ends of the controller 3 are connected with the first temperature sensor 14 and the second temperature sensor 24 respectively, and the output end thereof is connected with an inverter of the variable-frequency axial flow fan 22. For example, the controlled 3 receives a temperature signal form the first temperature sensor 14 and the second temperature sensor 24, automatically calculates a temperature difference between the inflow air temperature and the outflow air temperature in the air passage 101, and compares the temperature difference with a temperature difference set value so as to output a frequency signal of the fan 22 according to a corresponding control logic, thus adjusting the rotational speed of the fan 22, varying air volume of the fan 22, and adjusting refrigerating capacity accurately and automatically.

The heat exchanger 12 is arranged so that the flow rate of refrigerant therein does not need to be adjusted when the refrigerating capacity thereof increases several times. The air conditioner terminal device 100 can fill the heat exchanger with a adequate amount of refrigerant so that even when the refrigerating capacity of the air conditioner terminal device 100 increases several times, it can be ensured that the refrigerant may flow out of the heat exchanger 12 in a form of gas-liquid two-phase fluid and gas-phase fluid, providing adequate refrigerating capacity without complex refrigerant flow control, and having a simple refrigerating circulation. In an embodiment, a throttle device, which comprises a capillary or an expansion valve, is not required to be provided upstream of the heat exchanger 12.

When other air conditioner terminal devices of the data center can not provide effective refrigerating due to malfunction, air temperature at the air suction port 11 of the air conditioner terminal device 100 will rise. When the temperature difference between the inflow air temperature in the air passage 101 detected by the first temperature sensor 14 and the outflow air temperature in the air passage 101 detected by the second temperature sensor 24 exceeds the temperature difference set value, the controller 3 will raise the frequency of the fan 22 automatically so as to enlarge circulating air volume. Meanwhile, the operation control of cold source device will be made an adjustment accordingly. For example, the flow rate of chilled water which exchanges heat with the refrigerant will be increased, and even the water supplying temperature set of the chilled water can be lowered so as to meet higher heat dissipation requirements. The air conditioner terminal device 100 is a air conditioner terminal device 100 whose refrigerating capacity is automatically adjustable, i.e., the air conditioner terminal device 100 can adjust rotational speed of the fan 22 automatically according to a temperature difference signal from the first temperature sensor 14 and the second temperature sensor 24, and further adjusts the refrigerating capacity of the air conditioner terminal device 100 automatically by adjusting rotational speed of the fan 22.

The air conditioner terminal device 100 is simple and compact in structure, and has a high refrigerating capacity which is adjustable. It can deal with high heat load density, cool down electronic loads having high heat density effectively, meet control requirements on machine room environment of the data center, and can also adjust refrigerating capacity automatically according to change of machine room heat load so as to ensure normal operation of IT devices and improve reliability of air conditioning system. Meanwhile, refrigerating capacity can be automatically increased when malfunction happens to other air conditioner terminal devices of the data center, thereby reducing redundancy of components of air conditioning system and lowering cost.

The air conditioner terminal device 100 has such advantages as good applicability, high utilizing rate of device, considerable energy saving effect, and excellent technical and economic performance, etc, and has a fine prospect of commercial development and application.

As shown in FIG. 2, an air conditioning apparatus comprises the above-described air conditioner terminal device 100, a condenser 200, a pump 300 and a circulating pipeline 400 communicating the air conditioner terminal device 100, the condenser 200 and the pump 300. The pump 300 forces refrigerant to circulate between the air conditioner terminal device 100 and the condenser 200 via the circulating pipeline 400.

In an optional embodiment, the air conditioning apparatus comprises more than two air conditioner terminal devices 100. In the data center shown in FIG. 2, the air conditioning apparatus illustratively comprises three air conditioner terminal devices 100. However, the number of air conditioner terminal devices 100 contained in the air conditioning apparatus is not limited to be three. The number of air conditioner terminal devices 100 contained in the air conditioning apparatus can be appropriately chosen according to the amount of heat load generated by electronic loads in the data center.

Unlike conventional air conditioning devices, the air conditioning apparatus in accordance with the embodiment of the invention utilizes appropriate configuration so that a liquid-phase refrigerant performs phase transition heat release in the heat exchanger 12 so as to leave the heat exchanger 12 in gas-liquid two-phase or gas-phase fluid. The circulating pipeline 400 between the condenser 200 and the heat exchanger 12 of the air conditioner terminal devices 100 is not provided with a throttle device. In an embodiment, the condenser 200 is a water cooling condenser 200.

Further, as shown in FIG. 2, a schematic structural view of a data center 1000 of an embodiment is disclosed. The data center 1000 of the embodiment comprises a plurality of data device racks 500 and the above-described air conditioning apparatus. Each data device rack 500 comprises opposite first side 501 and second side 502. One said air conditioner terminal device 100 is provided above each rack 500, the air suction port 11 is located above the first side 501 of the data device rack 500 and the air discharge port 21 is located above the second side 502 of the data device rack 500.

Likewise, in the data center 1000 shown in FIG. 2, only three data device racks 500 and three air conditioner terminal devices 100 provided above the data device racks 500 have been schematically illustrated. However, the number of data device racks 500 and corresponding air conditioner terminal devices 100 provided above the data device racks 500 contained in the data center 1000 can be appropriately chosen according to actual application conditions of the data center 1000.

In the data center 1000, the air suction port 11 of the air conditioner terminal device 100 is located above the first side 501 of the data device rack 500, and the air discharge port 21 is located above the opposite second side 502 of the data device rack 500. In an embodiment, the first sides 501 of two adjacent rows of data device racks 500 face each other to form a first passage therebetween, and the second sides 502 of two adjacent rows of data device racks 500 face each other to form a second passage therebetween. Therefore, the air suction ports 11 of two adjacent air conditioner terminal devices 100 are close to each other and are located above the first passage between the data device racks 500, and the air discharge ports 21 of two adjacent air conditioner terminal devices 100 are close to each other and are located above the second passage between the data device racks 500. Apparently, the first passage has a higher temperature and is therefore the “hot passage” since inside the first passage, there is hot air to back to the air conditioner terminal device 100; and the second passage has a lower temperature and is therefore the “cold passage” since inside the second passage, there is cold air flowing out from the air conditioner terminal device 100. These “hot passage” and “cold passage” form an air curtain so as to prevent heat interference between the data device racks 500, thus realizing effective and reliable air circulation and improving refrigerating capacity of the air conditioner terminal device 100.

The air circulating process in the machine room of the data center 100 under a refrigerating working condition is described as follows. Hot air inside the “hot passage” between the data device racks 500 enters air passage of the air conditioner terminal device 100 via the air suction port 11, and sequentially flows through the air filter 15, the heat exchanger 12 and the fan 22 of the air conditioner terminal device 100, and is then discharged into the “cold passage” via the air discharge port 21, and finally flows through the data device racks 500, returns to the “hot passage” after absorbing heat generated by electronic loads such as data devices, thus completing one cycle.

When other air conditioner terminal devices 100 of the data center 1000 cannot provide effective refrigerating due to malfunction, air temperature in the “hot passage” will rise. When the temperature difference between the inflow air temperature detected by the first temperature sensor 14 and the outflow air temperature detected by the second temperature sensor 24 exceeds the temperature difference set value, the controller 3 will raise the frequency of the fan 22 automatically so as to enlarge circulating air volume and increase refrigerating capacity automatically, thus ensuring normal operation of data devices in the data center 1000. Meanwhile, redundancy design of the air conditioner terminal device 100 can be reduced and overall cost of the data center 1000 is lowered.

The above embodiments only serve for explaining the invention rather than limiting the invention. Those skilled in the art can make various modifications and variations without departing from the spirit and scope of the invention. Therefore, all the equivalent technical solutions also pertain to the scope of the invention and the protection scope of the invention should be defined by the appended claims.

What is claimed is:

1. An air conditioner terminal device comprising a heat exchanger, a variable-speed fan, an air passage communicating from an air suction port to an air discharge port, and refrigerant flowing through the heat exchanger, wherein the heat exchanger and the fan are installed in the air passage, the fan forces air within the air passage to flow towards the air discharge port from the air suction port, the refrigerant comes into heat contact with air within the air passage via the heat exchanger, the heat exchanger has an input joint and an output joint, the refrigerant flows in via the input joint and flows out from the output joint, and the refrigerant inside the input joint is liquid-phase fluid, whereas the refrigerant inside the output joint is gas-liquid two-phase fluid or gas-phase fluid.

2. The air conditioner terminal device according to claim 1, further comprising a temperature sensor for monitoring temperature in the air passage and a controller, wherein the controller is associated with the temperature sensor and the fan, and is arranged to vary the rotational speed of the fan according to the temperature detected by the temperature sensor.

3. The air conditioner terminal device according to claim 2, wherein the temperature sensor comprises a first temperature sensor and a second temperature sensor, the first temperature sensor is positioned between the air suction port and the heat exchanger, and the second temperature sensor is positioned between the heat exchanger and the air discharge port.

4. The air conditioner terminal device according to claim 3, wherein an air filter is further provided between the air suction port and the heat exchanger, and the first temperature sensor is positioned between the air filter and the heat exchanger.

5. The air conditioner terminal device according to claim 3, wherein the fan is a variable-frequency axial flow fan, and the controller is arranged to automatically adjust the rotational speed of the fan according to the difference between temperatures detected by the first temperature sensor and the second temperature sensor respectively.

6. The air conditioner terminal device according to claim 1, wherein no throttle device is provided upstream of the heat exchanger.

7. The air conditioner terminal device according to claim 1, wherein the heat exchanger is a coil heat exchanger.

8. An air conditioning apparatus, characterized by comprising the air conditioner terminal device according to claim 1, a condenser, a pump and a circulating pipeline communicating the air conditioner terminal device, the condenser and the pump, wherein the pump forces refrigerant to circulate between the air conditioner terminal device and the condenser via the circulating pipeline.

9. The air conditioning apparatus according to claim 8, wherein the condenser is a water-cooling condenser.

10. The air conditioning apparatus according to claim 8, comprising more than two air conditioner terminal devices.

11. A data center, comprising a plurality of data device racks and the air conditioning apparatus according to claim 8, wherein each rack has opposite first and second sides, one said air conditioner terminal device is provided above each rack, the air suction port is located above the first side and the air discharge port is located above the second side.

12. The data center according to claim 11, wherein the first sides of the two adjacent data device racks face each other to form a first passage therebetween, and the second sides of the two adjacent data device racks face each other to form a second passage therebetween, the air suction ports of two adjacent air conditioner terminal devices are close to each other and are located above the first passage between the data device racks, and the air discharge ports of two adjacent air conditioner terminal devices are close to each other and are located above the second passage between the data device racks.
